(19) United States
(12) Patent Application Publication
(10) Pub. No.: US 2026/0214784 A1
(43) Pub. Date: Jul. 23, 2026

(54) SUBSTRATE ASSEMBLY

(71) Applicant: FURUKAWA ELECTRIC CO., LTD., Tokyo (JP)

(72) Inventors: Yuta ISHIGE, Tokyo (JP); Wataru YOSHIDA, Tokyo (JP); Kazuya NAGASHIMA, Tokyo (JP); Hideyuki NASU, Tokyo (JP)

(73) Assignee: FURUKAWA ELECTRIC CO., LTD., Tokyo (JP)

(21) Appl. No.: 19/569,402

(22) Filed: Mar. 17, 2026

Related U.S. Application Data
(63) Continuation of application No. PCT/JP2024/033150, filed on Sep. 17, 2024.

(30) Foreign Application Priority Data
Sep. 27, 2023 (JP) 2023-164695

(51) Int. Cl. H05K 1/02

(52) U.S. Cl. CPC H05K 1/0203; H05K 2201/10325

(57) ABSTRACT

A substrate assembly includes: a substrate configured to fix an optical transceiver, the substrate including a first surface facing a first direction and a second surface facing an opposite direction on an opposite side of the first surface, wherein the optical transceiver includes a first electrical interface and a heat dissipation portion, and the first electrical interface and the heat dissipation portion are fixed to the substrate while facing the opposite direction and are arranged side by side with each other in a direction intersecting the first direction; a first heat dissipation mechanism including a first part that is adjacent to the heat dissipation portion in the first direction in a state where the optical transceiver is fixed to the substrate and that is thermally connected to the heat dissipation portion; and a thermal conductive member disposed between the heat dissipation portion and the first part.

This application is a continuation of International Application No. PCT/JP2024/033150, filed on Sep. 17, 2024 which claims the benefit of priority of the prior Japanese Patent Application No. 2023-164695, filed on Sep. 27, 2023, the entire contents of which are incorporated herein by reference.

### BACKGROUND

The present disclosure relates to a substrate assembly.

In the related art, there is a known small-sized optical transceiver described in Patent Document 1 as an optical transceiver that is used for a network switching device (for example, Japanese Laid-open Patent Publication No. 2020-27147).

### SUMMARY

In the network switching device that implements co-packaged optics (CPO), a switch application specific integrated circuit (ASIC) and a plurality of optical transceivers are mounted on a substrate.

With this type of network switching device, not only an amount of heat generation of the switch ASIC increases but also an amount of heat generation of the optical transceivers tends to increase in accordance with an increase in communication traffic.

There is a need for an improved novel substrate assembly capable of efficiently dissipating heat from optical transceivers as, for example, a substrate assembly that includes a substrate on which the optical transceivers are mounted.

According to one aspect of the present disclosure, there is provided a substrate assembly including: a substrate configured to fix an optical transceiver, the substrate including a first surface facing a first direction and a second surface facing an opposite direction of the first direction on an opposite side of the first surface, wherein the optical transceiver includes a first electrical interface and a heat dissipation portion, and the first electrical interface and the heat dissipation portion are fixed to the substrate while facing the opposite direction and are arranged side by side with each other in a direction intersecting the first direction; a first heat dissipation mechanism including a first part that is adjacent to the heat dissipation portion in the first direction in a state where the optical transceiver is fixed to the substrate and that is thermally connected to the heat dissipation portion; and a thermal conductive member disposed between the heat dissipation portion and the first part.

### BRIEF DESCRIPTION OF THE DRAWINGS

FIG. 1 is an exemplary and schematic perspective view of a switching device according to a first embodiment;

FIG. 2 is an exemplary and schematic plan view of the switching device according to the first embodiment;

FIG. 3 is an exemplary and schematic side view of a part of the switching device according to the first embodiment;

FIG. 4 is a cross-sectional view taken along line IV-IV illustrated in FIG. 2;

FIG. 5 is an exemplary and schematic plan view of a part of the switching device according to the first embodiment illustrating a state before the optical transceiver is mounted, a state after the optical transceiver has been mounted, and a state in which the optical transceiver has been attached;

FIG. 6 is an exemplary and schematic cross-sectional view of a part of a switching device according to a second embodiment;

FIG. 7 is an enlarged view of a VII portion illustrated in FIG. 6 illustrating a state before assembly;

FIG. 8 is an enlarged view of the VII portion illustrated in FIG. 6 illustrating a state after the assembly;

FIG. 9 is an exemplary and schematic cross-sectional view of a part of a switching device according to a third embodiment;

FIG. 10 is an exemplary and schematic cross-sectional view of a part of a switching device according to a fourth embodiment;

FIG. 11 is an enlarged cross-sectional view of the VII portion according to a modification of the embodiment when viewed from a position equivalent to that illustrated in FIG. 6, and is a diagram illustrating a state after the assembly;

FIG. 12 is an enlarged cross-sectional view of the VII portion according to another modification of the embodiment that is different from the VII portion illustrated in FIG. 11 when viewed from a position equivalent to that illustrated in FIG. 6, and is a diagram illustrating a state after the assembly;

FIG. 13 is an exemplary and schematic perspective view of a switching device according to a fifth embodiment;

FIG. 14 is an exemplary and schematic plan view of the switching device according to the fifth embodiment;

FIG. 15 is an exemplary and schematic side view of the switching device according to the fifth embodiment; and

FIG. 16 is an exemplary and schematic cross-sectional view of a part of a switching device of a sixth embodiment.

### DETAILED DESCRIPTION

Hereinafter, a plurality of exemplary embodiments will be disclosed below. Configurations of the embodiments described below, and operations and results (effects) implemented by the configurations are just examples. The present disclosure may be implemented by configurations other than the configurations disclosed in the embodiments described below. Furthermore, according to the present disclosure, it is possible to obtain at least one of various effects (including derivative effects) that are implemented by the configurations.

The embodiments described below have the same configurations. Therefore, according to the configurations of each of the embodiments, it is possible to implement the same operations and effects based on the same configurations. Furthermore, in the following, the same configurations are denoted by the same reference symbols, and, in some cases, repeated explanation may be omitted.

In each of the drawings, an arrow X indicates an X-direction, an arrow Y indicates a Y-direction, and an arrow Z indicates a Z-direction. The X-direction, the Y-direction, and the Z-direction intersect with each other and are perpendicular to one another.

### First Embodiment

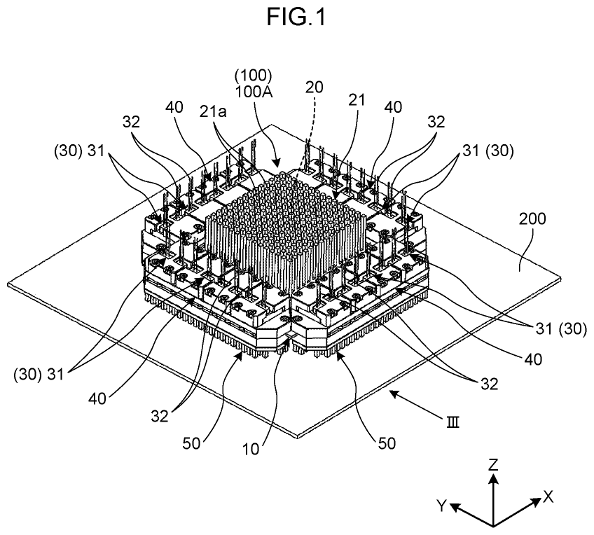

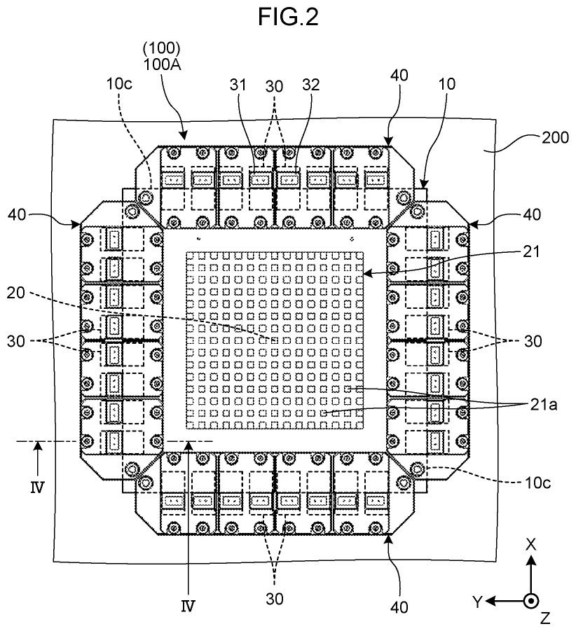

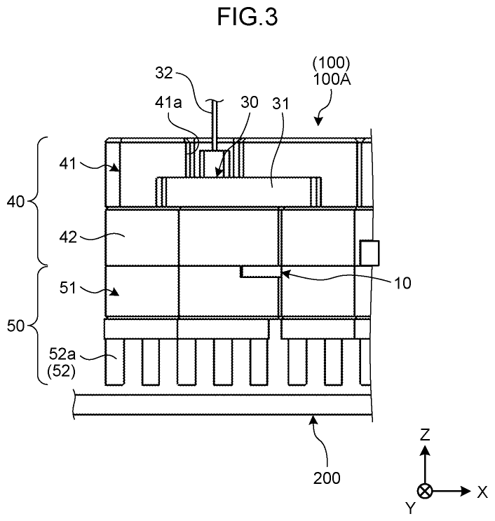

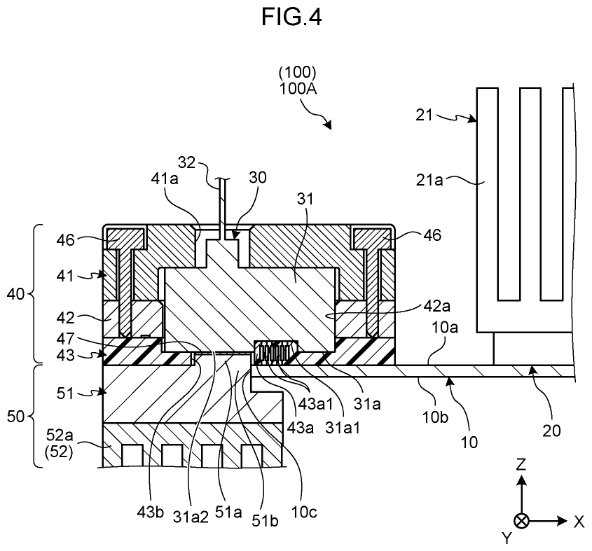

FIG. 1 is a perspective view of a switching device 100A (100) according to a first embodiment. FIG. 2 is a plan view of the switching device 100. FIG. 3 is a side view of a part of the switching device 100 when viewed at an arrow III from the Y-direction illustrated in FIG. 1. Furthermore, FIG. 4 is a cross-sectional view taken along line IV-IV illustrated in FIG. 2.

As illustrated in FIG. 1, the switching device 100 is mounted on a motherboard 200. Moreover, in the present embodiment, only a single piece of the switching device 100 is mounted on the motherboard 200, but a plurality of the switching devices 100 may be mounted on the motherboard 200. The motherboard 200 is one example of an integrated substrate.

As illustrated in FIGS. 1 and 2, the switching device 100 includes a substrate 10, a switch ASIC 20, the plurality of optical transceivers 30, a heat sink 21 used for the switch ASIC 20, a fixation mechanism 40 that fixes the optical transceivers 30 to the substrate 10, and a heat dissipation mechanism 50 for the optical transceivers 30. The substrate 10, the fixation mechanism 40, and the heat dissipation mechanism 50 are referred to as substrate assembly from among the components included in the switching device 100. The substrate assembly is able to be mounted on the motherboard 200.

As illustrated in FIG. 2, the substrate 10 has a square shape (quadrangular shape). Furthermore, as illustrated in FIG. 4, the substrate 10 includes a surface 10a that extends in a direction that intersects and is also perpendicular to the Z-direction, that has a plate-like shape, and that faces the Z-direction, and a surface 10b that is disposed on a side opposite to a side on which the surface 10a is disposed and that faces a direction opposite to the Z-direction. The surfaces 10a and 10b extend in a direction that intersects and is also perpendicular to the Z-direction. The substrate 10 is, for example, a printed circuit board. The Z-direction is one example of a first direction of the substrate 10, and is also referred to as a thickness direction of the substrate 10. The surface 10a is one example of a first surface, whereas the surface 10b is one example of a second surface.

Each of the optical transceivers 30 illustrated in FIGS. 1 to 4 receives an optical signal transmitted through an optical fiber 32, and outputs an electrical signal in accordance with the optical signal. The electrical signal that has been output from the optical transceivers 30 is input to the switch ASIC 20 via a socket 43 (see FIG. 4) and via a conducting body that is provided on the substrate 10. The optical transceiver 30 includes a photodiode array (not illustrated) as a plurality of light receiving portions that receive the optical signal. Furthermore, each of the optical transceivers 30 receives the electrical signal from the switch ASIC 20 via the substrate 10 and the conducting body that is provided on the socket 43, and outputs the optical signal in accordance with the electrical signal. The optical signals that have been output from the respective optical transceivers 30 are coupled to the optical fibers 32, and are transmitted by the respective optical fibers 32. The optical transceivers 30 include, for example, a vertical cavity surface emitting laser (VCSEL) array (not illustrated) as a plurality of light emitting portions each of which outputs the optical signal.

As illustrated in FIG. 2, the plurality of optical transceivers 30 are arranged along each of the sides 10c of the substrate 10. Furthermore, in the present embodiment, as illustrated in FIG. 4, each of the optical transceivers 30 are mounted so as to cover the corresponding sides 10c. In other words, each of the optical transceivers 30 is provided so as to step over the corresponding side 10c when viewed from the opposite side of the Z-direction, and includes a part that is located on the inner side of the corresponding side 10c and a part that is located on an outer side of the corresponding side 10c. As a result of this, this is advantageous in that it is possible to easily avoid interference between the optical fibers 32 extending from the respective optical transceivers 30 and the other parts, such as the switch ASIC 20 and the heat sink 21, or the like that are mounted on the substrate 10, and it is possible to allow for a smaller configuration of the substrate 10.

Furthermore, as illustrated in FIGS. 1 and 2, the plurality of optical transceivers 30 are fixed to the substrate 10 by the fixation mechanism 40 that is provided for each of the sides 10c of the substrate 10. The fixation mechanism 40 is provided on each of the four sides 10c, that is, four fixation mechanisms 40 are provided, and is shared by the plurality of optical transceivers 30 (as one example, eight pieces in the present embodiment) that are arranged along the corresponding sides 10c. In this way, as a result of the fixation mechanisms 40 being shared with the plurality of optical transceivers 30, for example, as compared with a case in which the optical transceivers 30 are fixed to the substrate 10 by the corresponding fixation mechanisms, this is advantageous in that it is possible to simplify an attachment structure of the fixation mechanisms 40 with respect to the substrate 10 and it is possible to reduce the number of parts, and, in addition, it is possible to reduce effort and cost needed to manufacture the switching device 100.

As illustrated in FIGS. 1 and 2, the switch ASIC 20 is mounted on the substrate 10 at a position (as one example, at substantially central part of the substrate 10 in the present embodiment) away from each of the sides 10c of the substrate 10. As illustrated in FIG. 4, the switch ASIC 20 is mounted on the surface 10a by using, for example, a flip-chip packaging technology. The switch ASIC 20 controls an operation of each of the optical transceivers 30. The switch ASIC 20 is one example of a semiconductor integrated circuit.

As illustrated in FIG. 4, the heat sink 21 is provided so as to come into contact with the side opposite to the side on which the substrate 10 is disposed with respect to the switch ASIC 20. The heat sink 21 comes into contact with a top surface of the switch ASIC 20, and includes a plurality of fins 21a each of which is formed in an array shape and in a pin shape and protrudes from the base in the Z-direction. Furthermore, the heat sink 21 is made of a material, such as an aluminum-based metal material, that has a relatively high thermal conductivity. With this configuration, heat generated at the switch ASIC 20 is transferred in the Z-direction at the heat sink 21, and is then transferred to the surrounding gas through heat exchange between the fins 21a and the gas surrounding the fins 21a, that is, is then dissipated. The heat sink 21 is one example of a second heat dissipation mechanism.

As illustrated in FIGS. 3 and 4, in the present embodiment, as one example, each of the fixation mechanisms 40 includes an upper side member 41, an intermediate member 42, and the socket 43. The constituting elements of the respective fixation mechanisms 40 are integrated by a fixation tool 46, such as a screw. Furthermore, among the constituting elements included in the respective fixation mechanisms 40, the intermediate member 42 and the socket 43 are shared by all of the optical transceivers 30 that are included in a group of the plurality of optical transceivers 30 disposed along the sides 10c of the substrate 10. As illustrated in FIG. 4, each of the fixation mechanisms 40 is fixed to the substrate 10 while sandwiching the optical transceivers 30 located in the vicinity of the respective sides 10c of the substrate 10 in the thickness direction of the substrate 10.

Furthermore, the fixation mechanism 40 removably fixes the optical transceiver 30 to the substrate 10 in order to allow for a replacement of the optical transceiver 30 that has been mounted. In order to implement this, in the present embodiment, the constituting elements included in the fixation mechanism 40 includes a constituting element that is fixed to the substrate 10, and a constituting element that is removable with respect to the substrate 10. In the present embodiment, the configuration has been constituted such that the intermediate member 42 and the socket 43 are fixed to the substrate 10, and the upper side member 41 is removably constituted with respect to the intermediate member 42, that is, the substrate 10. Specifically, as illustrated in FIG. 4, the upper side member 41 is attached to the intermediate member 42 by the fixation tool 46 that has been configured as a detachable screw. Each of the intermediate member 42 and the socket 43 is one example of a first member, whereas the upper side member 41 is one example of a second member.

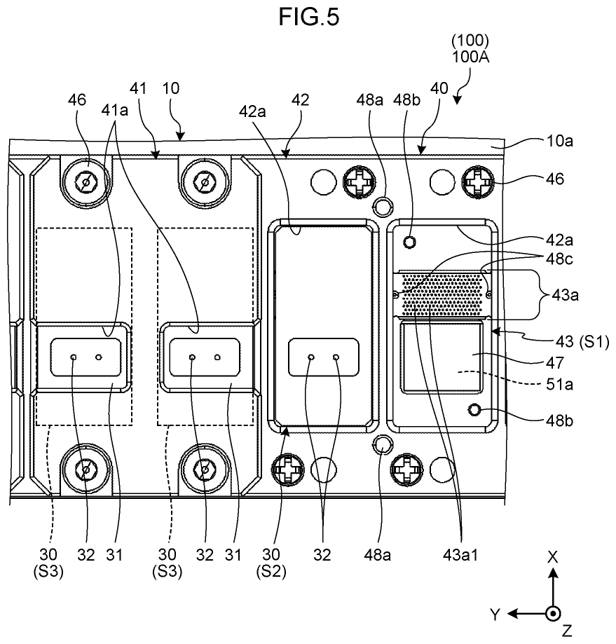

FIG. 5 is a plan view illustrating a state S1 before the optical transceiver 30 is placed, a state S2 after the optical transceiver 30 has been placed, and a state S3 in which the optical transceiver 30 has been mounted. As indicated by the state S3 illustrated in FIG. 5, in the present embodiment, the upper side member 41 is not shared by all of the plurality of optical transceivers 30 among the plurality of optical transceivers 30 disposed along the side 10c, but is shared only by the two adjacent optical transceivers 30 that are disposed along the side 10c. As a result of this, for example, this is advantageous in that it is possible to satisfy both of simplification of a removal process of each of the optical transceivers 30 and the sharing of parts, it is possible to further improve the accuracy of positioning by reducing the effects of bending of each of the fixation mechanisms 40, or a manufacturing variation in the constituting elements included in the fixation mechanisms 40, the optical transceivers 30, or the like. However, the configuration described above is one example, and the upper side member 41 may be shared by all of the plurality of optical transceivers 30 disposed along the side 10c.

The optical transceiver 30 includes a body 31 and the plurality of optical fibers 32. Moreover, in the description below, the description will be made in a state in which the optical transceiver 30 has been fixed to the substrate 10 unless otherwise stated.

As illustrated in FIG. 4, the body 31 has a surface 31a that faces a direction opposite to the Z-direction. An electrical interface 31a1 on which an array of a plurality of electrodes (not illustrated) are provided, and a heat dissipation surface 31a2 are provided on the surface 31a. In a fixed state, both of the electrical interface 31a1 and the heat dissipation surface 31a2 face a direction opposite to the Z-direction, and are arranged side by side with each other substantially along the surface 10a of the substrate 10 in a direction intersecting the side 10c of the substrate 10 (the X-direction, as for the optical transceiver 30 illustrated in FIG. 4). The heating element included in the interior of the optical transceiver 30 is arranged side by side with the heat dissipation surface 31a2 in the Z-direction. The electrical interface 31a1 is one example of a first electrical interface, and the heat dissipation surface 31a2 is one example of a heat dissipation portion.

The plurality of optical fibers 32 extend from a part that is away from the surface 31a of the body 31, specifically, extend from a part that is disposed side by side with the heat dissipation surface 31a2 in the Z-direction on the side opposite to the side on which the heat dissipation surface 31a2 is disposed. Furthermore, the plurality of optical fibers 32 extend from the body 31 in the Z-direction in the vicinity of the body 31.

The socket 43, the intermediate member 42, and the upper side member 41 are placed on the substrate 10 in this order.

The upper side member 41 presses the body 31 of the optical transceiver 30 toward the substrate 10 and the socket 43 in a direction opposite to the Z-direction. Furthermore, as illustrated in FIGS. 4 and 5, an opening 41a that functions as a notch that passes through the upper side member 41 in the Z-direction is provided at the upper side member 41. A part of the body 31 is accommodated in the opening 41a, and the optical fibers 32 extend passing through the opening 41a.

An opening 42a that functions as a through hole and that extends in the Z-direction is provided in the intermediate member 42. The surface disposed on the opening 42a has a function to roughly guide the X-direction and the Y-direction at the time at which the body 31 of the optical transceiver 30 is mounted.

The socket 43 is placed on the surface 10a of the substrate 10, and supports the body 31 of the optical transceiver 30. An electrical interface 43a and an opening 43b are provided at the socket 43.

The electrical interface 43a faces and comes into contact with the electrical interface 31a1 that is provided in the body 31 of the optical transceiver 30, and includes a conducting body 43a1 that is electrically connected to each of a plurality of electrodes that are provided at the electrical interface 31a1. The conducting body 43a1 is able to be configured as a contact terminal that includes an elastically extendable pin that extends in, for example, the Z-direction. The conducting body 43a1 is electrically connected to a conducting body (not illustrated) of the substrate 10. Each of the electrodes provided at the electrical interface 31a1 included in the optical transceiver 30 is electrically connected to the conducting body of the switch ASIC 20 via the conducting body 43a1 included in the electrical interface 43a provided at the socket 43 and the conducting body of the substrate 10. By providing the socket 43 including the electrical interface 43a, for example, as compared with a case in which the electrical interface 43a is directly provided on the substrate 10, this is advantageous in that it is possible to further easily construct a configuration in which required accuracy of positioning of the plurality of electrodes is able to be ensured. The electrical interface 43a is one example of a second electrical interface.

The opening 43b allows the heat dissipation surface 31a2 that is provided in the body 31 of the optical transceiver 30 to be exposed in a direction opposite to the Z-direction. The opening 43b is provided as, for example, a through hole or a notch that passes through the socket 43 extends in the Z-direction.

The heat dissipation mechanism 50 dissipates heat generated at the optical transceiver 30. The heat dissipation mechanism 50 includes a lower side member 51 and a heat sink 52. Moreover, in the heat dissipation mechanism 50, at lease the lower side member 51 may be configured to function as a part of the fixation mechanism 40. The heat dissipation mechanism 50 is one example of the first heat dissipation mechanism.

The lower side member 51 is located on the side opposite to the side on which the intermediate member 42 is disposed, with respect to the socket 43. The lower side member 51 includes a first part 51a that is accommodated in an interior of the opening 43b, and a second part 51b that is arranged side by side with the first part 51a in the direction intersecting the Z-direction with respect to the substrate 10. The lower side member 51 is thermally connected to the heat dissipation surface 31a2 of the optical transceiver 30, and transfers the heat generated at the optical transceiver 30. The lower side member 51 is made of, for example, a material, such as an aluminum-based metal material, having relatively high thermal conductivity. Furthermore, the lower side member 51 is fixed to the substrate 10 or the fixation mechanism 40 by using a fixation tool, such as a screw, or using an adhesive, or the like. The lower side member 51 may also be referred to as a heat transfer member. Moreover, in the present specification, a case in which two members are thermally connected refers to a state in which the two members are capable of heat conduction.

The first part 51a is adjacent to the heat dissipation surface 31a2 via a thermal conductive member 47 having a property of flexibility, and is thermally connected to the heat dissipation surface 31a2. By providing the thermal conductive member 47, this is advantageous in that it is possible to suppress a reduction in thermal conductivity efficiency from the heat dissipation surface 31a2 to the first part 51a as a result of a gap between the heat dissipation surface 31a2 and the first part 51a being generated due to a manufacturing variation, a difference between coefficients of thermal expansion between parts, or the like, or it is possible to suppress an excessive pressure force from being generated between the heat dissipation surface 31a2 and the first part 51a.

The thermal conductive member 47 includes a synthetic resin material, thereby having the properties of elasticity, flexibility, and suppleness, so that the thermal conductive member 47 is able to come into contact with both of the heat dissipation surface 31a2 and the first part 51a, and is able to be in close contact with both of the heat dissipation surface 31a2 and the first part 51a. The thermal conductive member 47 is disposed between the heat dissipation surface 31a2 and the first part 51a in an elastically compressed state. Specifically, the thermal conductive member 47 is formed of, for example, a synthetic resin material made of an acrylic resin or a silicone resin as the main material, and may include a filler having, for example, thermal conductivity made of boron nitride, aluminum nitride, alumina, or the like. Furthermore, the thermal conductive member 47 may include, for example, a thin film made of graphite and a layer that sandwiches the thin film and that is formed of a synthetic resin material made of, for example, polyethylene terephthalate or polyimide. Furthermore, the thermal conductive member 47 may be formed of a rubber material having thermal conductivity. The rubber material is made of, for example, silicone, acrylic, or the like as the main material, and may include a filler that has a thermal conductivity and that is made of boron nitride, aluminum nitride, alumina, nanodiamond, or the like. However, the structure of the thermal conductive member 47 is not limited to the examples described above, and the thermal conductive member 47 may have another structure having the properties of elasticity, flexibility, and suppleness.

The second part 51b is integrally provided with the first part 51a and is thermally connected to the first part 51a. Furthermore, the second part 51b extends from the first part 51a in a direction opposite to the Z-direction, that is, in the thickness direction of the substrate 10, at a position parallel to the direction (the X-direction in terms of the lower side member 51 illustrated in FIG. 4) intersecting the Z-direction with respect to the substrate 10.

Furthermore, the lower side member 51 comes into contact with the heat sink 52 on the side opposite to the side, on which the heat dissipation surface 31a2 is disposed, with respect to the substrate 10, and is thermally connected to the heat sink 52. The heat sink 52 includes a plurality of fins 52a that are formed in an array shape and a pin shape and that protrude from the base in a direction opposite to the Z-direction. Furthermore, the heat sink 52 is made of a material, such as an aluminum-based metal material, that has a relatively high thermal conductivity. Furthermore, the heat sink 52 is fixed to the lower side member 51 by using a fixation tool, such as a screw, or using soldering, an adhesive, or the like. Moreover, the lower side member 51 and the heat sink 52 may be integrally formed as a single member. The heat sink 52 may also be referred to as a heat transfer member or a heat dissipation member.

With the lower side member 51 and the heat sink 52 each having the above described configuration, the heat generated in the optical transceiver 30 is transferred from the heat dissipation surface 31a2 in the direction opposite to the Z-direction at the lower side member 51 and the heat sink 52, and is then transferred to the surrounding gas through heat exchange between the fin 52a and the gas surrounding the fin 52a, that is, is then dissipated. Moreover, the switching device 100 may be configured to have an electrically driven fan, and may be configured such that a flow of air generated by an operation of the electrically driven fan acts on the heat sink 52.

Furthermore, as can be seen from FIGS. 2, 4, and 5, the heat dissipation surface 31a2 is located on the side opposite to the side on which the switch ASIC 20 is disposed, with respect to the electrical interface 31a1. With this arrangement, for example, this is advantageous in that it is easily secure a transmission property required for the electrical signal as a result of shortening the length of the conducting body between the electrical interface 31a1 and the switch ASIC 20, or it is possible to easily obtain a required heat dissipation property from the optical transceiver 30 as a result of allowing for avoidance of an interference with the first heat dissipation mechanism and the conducting body.

Furthermore, a positioning mechanism 48a illustrated in FIG. 5 performs positioning of the intermediate member 42 and the upper side member 41 in the direction intersecting the Z-direction. A positioning mechanism 48b performs positioning of the socket 43 and the optical transceiver 30 in the direction intersecting the Z-direction. Furthermore, a positioning mechanism 48c performs positioning of the substrate 10 and the socket 43 in the direction intersecting the Z-direction. Each of the positioning mechanisms 48a to 48c is constituted by, for example, a member provided with a pin and a hole in which the pin is inserted. Furthermore, each of the positioning mechanisms 48a to 48c is provided at two positions that are away from one another. Among the positioning mechanisms 48a to 48c, the two positioning mechanisms 48b that are disposed at two positions are provided such that the electrical interface 43a is arranged between the two positioning mechanisms 48b that are disposed at the two positions. As a result of this, it is possible to perform the positioning of the electrodes of the electrical interface 31a1 (see FIG. 4) included in the optical transceiver 30 and the conducting body 43a1 of the electrical interface 43a included in the socket 43 with higher precision.

As described above, according to the present embodiment, it is possible to obtain an improved novel substrate assembly capable of efficiently dissipating heat generated at the optical transceivers 30 while avoiding an interference with the other parts by the heat dissipation mechanism 50. Furthermore, in the present embodiment, the optical transceiver 30 is arranged so as to face one of the surfaces of the substrate 10, and also, the heat dissipation mechanism 50 is arranged so as to face the other of the surfaces of the substrate 10 or arranged on an outer side of the side 10c of the substrate 10. As a result of this, this is advantageous in that it is possible to further increase a packaging density of the optical transceiver 30 as a result of allowing for avoidance of an interference with the heat dissipation mechanism 50. Furthermore, it is possible to suppress an increase in size of the switching device 100 in the direction along the surface of the substrate 10 as a result of allowing for pulling the optical fibers 32 out from the optical transceiver 30 in a direction intersecting the surface of the substrate 10. Furthermore, this is advantageous in that it is possible to further increase a degree of freedom of an arrangement direction of the optical fibers 32, and, furthermore, it will be easier to avoid an interfere with the other part, such as the ASIC 20. In addition, as a result of allowing for avoidance with an interfere with the optical transceiver 30, this is advantageous in that it is possible to increase a degree of freedom of an arrangement or the structure of the heat dissipation mechanism 50, it is possible to more easily increase heat dissipation efficiency of the heat dissipation mechanism 50 both in a case where a cooling system of the heat dissipation mechanism 50 is a water cooling system and in a case where a cooling system of the heat dissipation mechanism 50 is an air cooling system, or it is possible to configure the heat dissipation mechanism 50 in a more compact form.

Furthermore, in the present embodiment, the thermal conductive member 47 is disposed between the heat dissipation surface 31a2 (heat dissipation portion) of the optical transceiver 30 and the first part 51a of the heat dissipation mechanism 50 (the first heat dissipation mechanism). If the thermal conductive member 47 is not provided, heat dissipation by the heat dissipation mechanism 50 may possibly decrease as a result of an increase in thermal impedance between the heat dissipation surface 31a2 and the first part 51a. On this point, according to the present embodiment, it is possible to further efficiently transfer the heat generated at the optical transceivers 30 to the first part 51a, that is, the heat dissipation mechanism 50, via the thermal conductive member 47, and it is possible to further efficiently dissipate the heat from the heat dissipation mechanism 5.

Furthermore, as described above in the present embodiment, in a case of a configuration in which the plurality of optical transceivers 30 are arranged side by side with each other in a direction along the sides 10c of the substrate 10, it is possible to increase the number of optical transceivers 30 that are able to be mounted as the width of each of the optical transceivers 30 arranged along the sides 10c is smaller. With the configuration according to the present embodiment, for example, it is possible to mount the optical transceivers 30 each having a width equal to or less than 10 [mm] or a width equal to or less than 8 [mm]. Furthermore, in this case, it is possible to mount the optical transceivers 30 whose transmission capacity is, for example, equal to or greater than 200 [Gb/s], 400 [Gb/s], or 800 [Gb/s].

### Second Embodiment

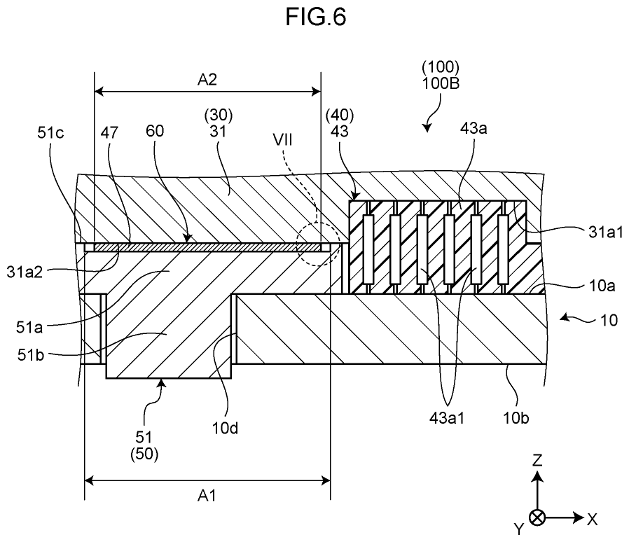

FIG. 6 is a cross-sectional view of a part of a switching device 100B (100) according to a second embodiment when viewed from a position equivalent to that illustrated in FIG. 4.

As illustrated in FIG. 6, in the present embodiment, a through hole 10d that passes through the substrate 10 in the Z-direction is formed in the substrate 10, and the second part 51b passes through the through hole 10d in the Z-direction. The second part 51b is one example of the third part that is provided in addition to the substrate 10. Moreover, in also the present embodiment, similarly to the above described first embodiment, it may be possible to provide the heat sink 52 that is adjacent to the lower side member 51 in the direction opposite to the Z-direction and that is thermally connected to the lower side member 51.

### [Setting of Compressibility Ratio of Thermal Conductive Sheet by Accommodation Section]

Furthermore, in the present embodiment, as illustrated in FIG. 6, an accommodation section 60 for the thermal conductive member 47 is provided between the heat dissipation surface 31a2 and the first part 51a. The accommodation section 60 is constituted as a concave portion that is concaved from an end surface 51c of the first part 51a in the Z-direction toward the direction opposite to the Z-direction. The end surface 51c intersects the Z-direction and extends perpendicular to the Z-direction, and is in contact with the heat dissipation surface 31a2 around the circumference of the accommodation section 60. Moreover, the end surface 51c does not need to be in contact with the heat dissipation surface 31a2 around the entire circumference of the accommodation section 60.

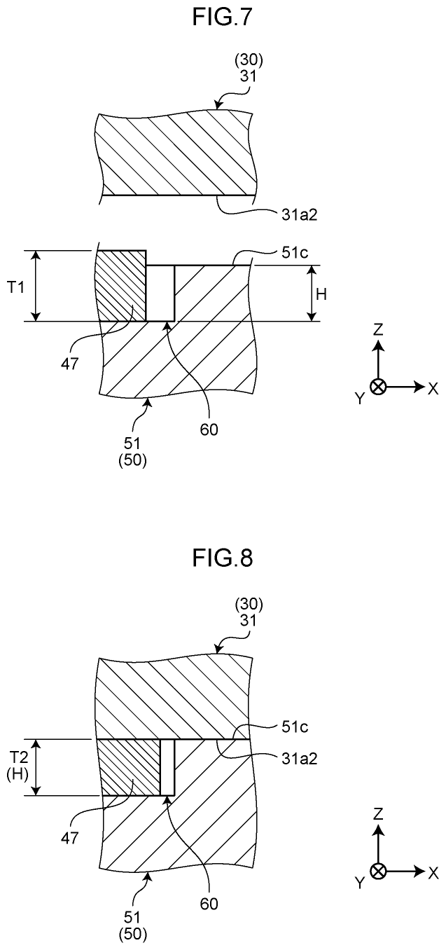

FIGS. 7 and 8 are enlarged views of a VII portion illustrated in FIG. 6. FIG. 7 illustrates a state before the optical transceiver 30 is mounted on the substrate 10, in other words, a state before the body 31 of the optical transceiver 30, the thermal conductive member 47, and the first part 51a included in the heat dissipation mechanism 50 are assembled. FIG. 8 illustrates a state after the optical transceiver 30 has been mounted on the substrate 10, in other words, a state after the body 31 of the optical transceiver 30, the thermal conductive member 47, and the first part 51a included in the heat dissipation mechanism 50 have been assembled.

As illustrated in FIG. 7, in the present embodiment, the accommodation section 60 is the concave portion that is concaved from the end surface 51c at a substantially constant depth (a height H). Furthermore, the thermal conductive member 47 has a substantially constant thickness T1 that is greater than the height H in a free state in which no external forces other than gravity and an atmospheric pressure act. The thermal conductive member 47 is accommodated in the accommodation section 60 in a state in which the thermal conductive member 47 intersects the Z-direction and extends perpendicular to the Z-direction. Then, as illustrated in FIG. 8, in the state after the body 31, the thermal conductive member 47, and the first part 51a have been assembled, the thermal conductive member 47 elastically compressed between the body 31 and the first part 51a in the Z-direction, and, as a result of this, the thickness of the thermal conductive member 47 becomes T2 (=H<T1) that is smaller than T1. The thickness T1 is a thickness in an uncompressed state in which the thermal conductive member 47 is not compressed by the two members that sandwich the thermal conductive member 47, that are, the body 31 and the lower side member 51. The thickness T1 is a thickness in an uncompressed state before, for example, the assembly of the switching device 100 (before the thermal conductive member 47 is mounted), or a thickness in an uncompressed state in which an assembly state has been released, that is, disassembled, after the assembly of the substrate assembly (after the thermal conductive member 47 has been mounted). The disassembly in this case may be disassemble immediately after the assembly, or may be disassemble after a relatively long period of time like, for example, several years since the assembly.

In a case where the thermal conductive member 47 is, for example, an elastic material made of elastomer, the thermal conductive member 47 is substantially uniformly and elastically compressed in the Z-direction at each of the positions in the direction intersecting the Z-direction. Here, a compressibility ratio R [%] of the thermal conductive member 47 due to the assembly may be defined by Equation (1) below.

R=(T1−H)/T1×100 (1 )

The thermal conductivity efficiency of the thermal conductive member 47 increases as an increase in a surface pressure acting on both sides of the surfaces (contact surface) in the thickness direction, and, when the surface pressure is equal to or greater than a threshold, the thermal conductivity efficiency enters a substantially saturation state. According to the inventors' careful examination, based on this point of view, it has been founded that the compressibility ratio R is preferably equal to or greater than 15 [%], is more preferably equal to or greater than 20 [%], and is even more preferably equal to or greater than 25 [%]. Furthermore, a repulsive force due to the thermal conductive member 47 increases as the compressibility ratio R increases, and, as a result of this, a stress generated in a coupling tool that couples the thermal conductive member 47, the body 31, the lower side member 51, and the optical transceiver 30 to the heat dissipation mechanism 50 increases. It is found that the compressibility ratio R is preferably equal to or less than 45 [%], is more preferably equal to or less than 40 [%], and is even more preferably equal to or less than 35 [%] in terms of preventing the stress from becoming excessively high.

Furthermore, in a case where an area of the optical transceiver 30 that is exposed to the accommodation section 60 is denoted by A1, and an area of the thermal conductive member 47 that comes into contact with the exposure surface is dented by A2, a ratio of contact Rc [%] of the thermal conductive member 47 with respect to the optical transceiver 30 may be defined Equation (2) below.

Rc=A2/A1×100 (2 )

The thermal conductivity efficiency of the thermal conductive member 47 increases as an increase in the area of the thermal conductive member 47 coming into contact with the optical transceiver 30. According to the inventors' careful examination, based on this point of view, it has been founded that the ratio of contact Rc is preferably equal to or greater than 15 [%], is more preferably equal to or greater than 30 [%], and is even more preferably equal to or greater than 50 [%]. Moreover, the area A1 may also be an area of cross section of the accommodation section 60 in a direction perpendicular to a compression direction (Z-direction) of the thermal conductive member 47.

In also the present embodiment, the heat generated at the optical transceivers 30 is transferred from the heat dissipation surface 31a2 to the lower side member 51 in the direction opposite to the Z-direction, and is then and dissipated. In also the present embodiment, it is possible to obtain the same effects as those described above in the first embodiment.

Furthermore, according to the present embodiment, the accommodation section 60 of the thermal conductive member 47 is provided, and it is possible to appropriately set the compressibility ratio R of the thermal conductive member 47 by setting the thicknesses T1 and T2 of the thermal conductive member 47 and the height H of the accommodation section 60. According to this configuration, for example, it is possible to easily set the efficiency of heat conduction due to the thermal conductive member 47 to a value equal to or greater than a required value. As a result of this, the heat generated by the optical transceivers 30 is able to be dissipated more reliably. Furthermore, it is possible to prevent the stress generated in each of the parts included in the switching device 100 from becoming excessively high in accordance with a compression repulsive force of the thermal conductive member 47. As a result of this, it is possible to prevent a deformation or damage of the parts.

### Third Embodiment

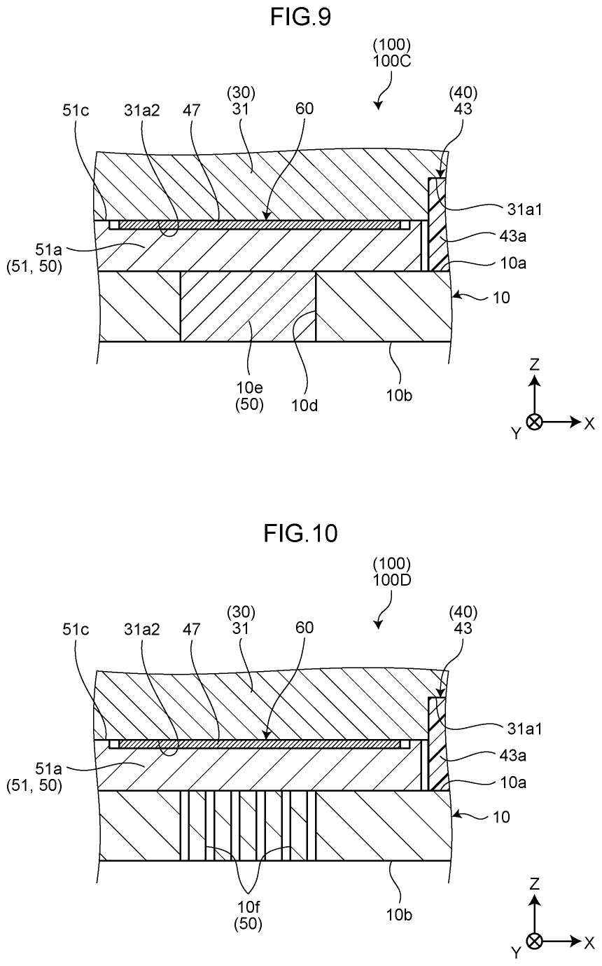

FIG. 9 is a cross-sectional view of a part of a switching device 100C (100) according to a third embodiment when viewed from a position equivalent to that illustrated in FIG. 4.

As illustrated in FIG. 9, in the present embodiment, an inlay 10e that passes through the substrate 10 in the Z-direction is provided in the substrate 10. The inlay 10e is made of, for example, a material, such as a copper based metal material, having a relatively high thermal conductivity. The inlay 10e is arranged side by side with the first part 51a of the lower side member 51 in the Z-direction, is in contact with the first part 51a, and is also thermally connected to the first part 51a. The inlay 10e constitutes a part of the heat dissipation mechanism 50, and is one example of the third part that is provided on the substrate 10. The inlay 10e is also referred to as a heat transfer member or a heat dissipation member. Moreover, in also the present embodiment, the heat sink 52 that is adjacent to the inlay 10e in the direction opposite to the Z-direction and that is thermally connected to the inlay 10e may also be provided.

In also the present embodiment, the heat generated at the optical transceivers 30 is transferred from the heat dissipation surface 31a2 toward the direction opposite to the Z-direction at the lower side member 51 and the inlay 10e, and is then dissipated. In also the present embodiment, it is possible to obtain the same effect as that obtained in the above described first embodiment.

### Fourth Embodiment

FIG. 10 is a cross-sectional view of a part of a switching device 100D (100) according to a fourth embodiment when viewed from a position equivalent to that illustrated in FIG. 4.

As illustrated in FIG. 10, in the present embodiment, a through-hole via 10f that passes through the substrate 10 in the Z-direction is provided in the substrate 10. The through-hole via 10f is made of, for example, a material, such as a copper based metal material, having a relatively high thermal conductivity. The through-hole via 10f may be solid, or may be hollow. In a case of hollow, the through-hole via 10f may be a plating layer. The through-hole via 10f is arranged side by side with the first part 51a included in the lower side member 51 in the Z-direction, is in contact with the first part 51a, and is also thermally connected to the first part 51a. The through-hole via 10f constitutes a part of the heat dissipation mechanism 50, and is one example of the third part that is provided on the substrate 10. The through-hole via 10f is also referred to as a heat transfer member or a heat dissipation member. Moreover, in also the present embodiment, the heat sink 52 that is adjacent to the through-hole via 10f in the direction opposite to the Z-direction and that is thermally connected to the through-hole via 10f may also be provided.

In also the present embodiment, the heat generated at the optical transceivers 30 is transferred from the heat dissipation surface 31a2 toward the direction opposite to the Z-direction at the lower side member 51 and the through-hole via 10f, and is then dissipated. In also the present embodiment, it is possible to obtain the same effect as that obtained in the above described first embodiment.

### [Modification of Accommodation Section]

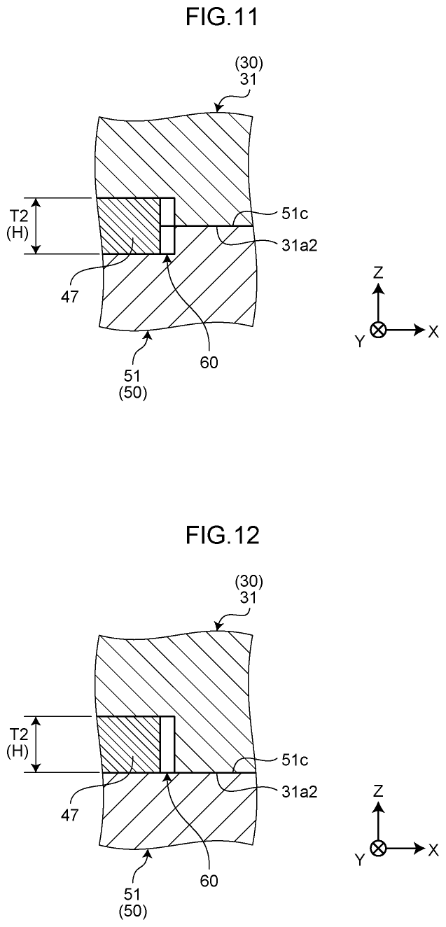

FIGS. 11 and 12 are cross-sectional view each illustrating a modification of the accommodation section 60. As illustrated in FIG. 11 as an example, the accommodation section 60 may be constituted by a concave portion that is concaved from the heat dissipation surface 31a2 in the Z-direction, and a concave portion that is concaved from the end surface 51c in the direction opposite to the Z-direction. Furthermore, as illustrated in FIG. 12 as an example, the accommodation section 60 may be constituted by only the concave portion that is concaved from the heat dissipation surface 31a2 in the Z-direction. With these modifications, it is possible to obtain the same effect as that obtained from the accommodation section 60 (FIG. 8) according to the second embodiment.

### Fifth Embodiment

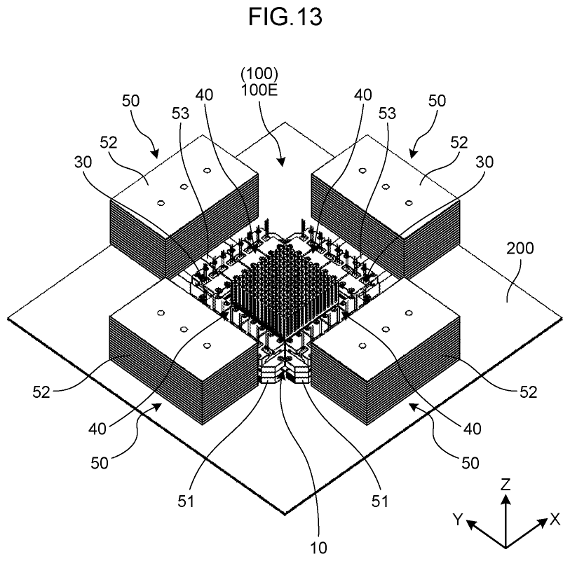

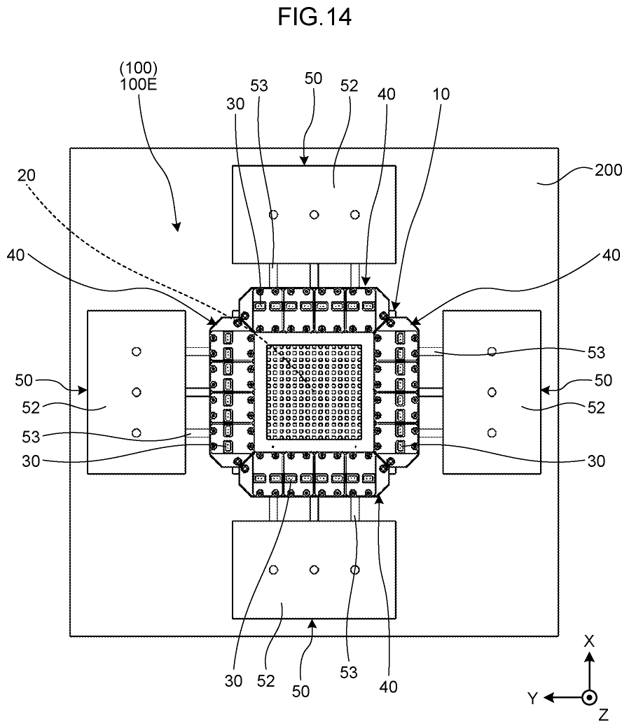

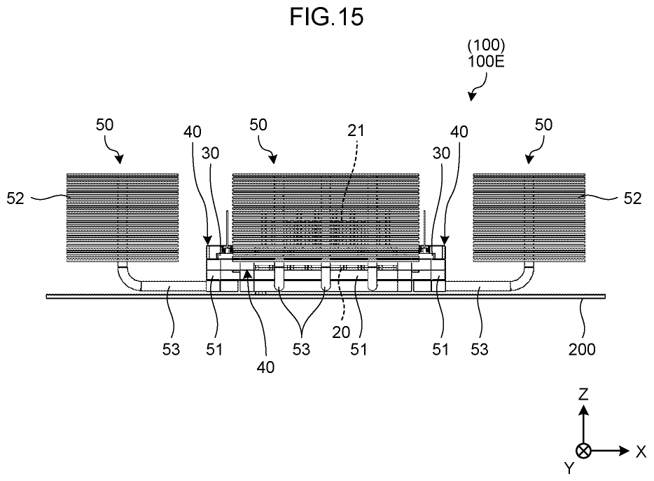

FIG. 13 is a perspective view of a switching device 100E (100) according to a fifth embodiment. FIG. 14 is a plan view of the switching device 100E (100). Furthermore, FIG. 15 is a side view of the switching device 100E (100).

As illustrated in FIGS. 13 to 15, in the present embodiment, the heat dissipation mechanism 50 has a structure in which a heat pipe 53 that transport heat using a refrigerant is provided between the lower side member 51 and the heat sink 52. The heat pipe 53 transports the heat from the lower side member 51 to the heat sink 52 in a gaseous state after the refrigerant is heated by the lower side member 51, and returns the refrigerant in a liquid state after being cooled by the heat sink 52 to the lower side member 51. The heat pipe 53 is one example of the heat transport mechanism.

By providing the heat pipe 53, for example, it is possible to dissipate the heat from a location in which heat is easily dissipated, and, in addition, this is advantageous in that it is possible to further efficiently cool the optical transceiver 30.

Moreover, the heat pipe 53 may be thermally connected to the heat sink 52 used for the switch ASIC 20. In this case, it is possible to share the heat sink 52 by the switch ASIC 20 and the optical transceiver 30, so that it is possible to reduce the number of parts, which offers an advantage in that it is possible to reduce, for example, manufacturing effort and cost.

### Sixth Embodiment

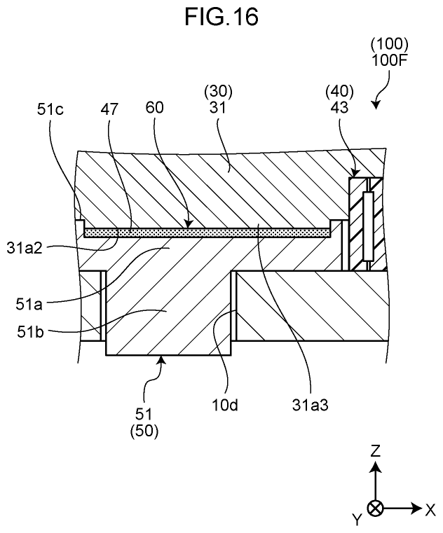

FIG. 16 is a cross-sectional view of a part of a switching device 100F (100) according to a sixth embodiment when viewed from a position equivalent to that illustrated in FIG. 4. In the present embodiment, the thermal conductive member 47 is grease having thermal conductivity. The grease is made of, for example, silicone, ester, ether, polyalphaolefin, or the like as the main material, and may also include a filler made of boron nitride, aluminum nitride, alumina, or nanodiamond having thermal conductivity. In this way, in also a case in which the thermal conductive member 47 is a semi-solid liquid, such as grease, it is also possible to obtain the same effect as that described above in the embodiment.

In a case where the thermal conductive member 47 is grease, it is known that thermal conductivity is higher in a compressed state than in an uncompressed state. Accordingly, in the present embodiment, it is configured such that a protrusion portion 31a3 that is inserted in the accommodation section 60 and that functions as a concave portion is provided in the body 31 of the optical transceiver 30, and at the time of assembly of the switching device 100, the protrusion portion 31a3 compresses the thermal conductive member 47 in the interior of the accommodation section 60. Furthermore, in this case, a clearance between an outer periphery surface of the protrusion portion 31a3 and an inner periphery surface of the accommodation section 60 is set to a size that prevents the compressed thermal conductive member 47 that is grease from leaking out such that the thermal conductive member 47 is more certainly compressed in the interior of the accommodation section 60. With this configuration, the surface at the tip of the protrusion portion 31a3 corresponds to the heat dissipation surface 31a2. The protrusion portion 31a3 may also be referred to as an inserted portion that is inserted into the accommodation section 60, or is referred to as a pressing part that presses the thermal conductive member 47.

In a case where the volume of the accommodation section 60 is V0, the thermal conductive member 47 with a volume of V1 (<V0) in an uncompressed state is accommodated in the interior of the accommodation section 60 before assembly of the switching device 100. Then, at the time of assembly of the switching device 100, the protrusion portion 31a3 is accommodated in the interior of the accommodation section 60, and a volume V2 of the thermal conductive member 47 that is sandwiched between the protrusion portion 31a3 and the accommodation section 60 is set to be smaller than the volume V1, that is, set to be compressed.

In this case, the compressibility ratio R [%] of the thermal conductive member 47 associated with the assembly may be defined as Expression (3) below.

R=(V1−V2)/V2×100 (3 )

According to the inventors'earnest research, from the perspective of further increasing thermal conductivity, it has been founded that the compressibility ratio R is preferably equal to or greater than 5[%], is more preferably equal to or greater than 10 [%], and is even more preferably equal to or greater than 15 [%]. Furthermore, as the compressibility ratio R increases, the thermal conductive member 47 is likely to leaking out from the clearance and the repulsive force due to the thermal conductive member 47 increases, and, as a result of this, a stress generated in a coupling tool that couples the thermal conductive member 47, the body 31, the lower side member 51, and the optical transceiver 30 to the heat dissipation mechanism 50 increases. It is found that the compressibility ratio R is preferably equal to or less than 40 [%], is more preferably equal to or less than 35 [%], and is even more preferably equal to or less than 30 [%] in terms of preventing the stress from becoming excessively high while suppressing a leakage from the clearance.

In also the present embodiment, it is also possible to obtain the same effect as that obtained from the other embodiment in which the thermal conductive member 47 is provided. Moreover, the configuration of the switching device 100 constituted in a case where the thermal conductive member 47 is grease is not limited to the above described embodiment. For example, instead of the protrusion portion 31a3, a member that is different from the optical transceiver 30 and that comes into contact with (preferably, closely adhere to) the surface disposed on the lower side member 51 side of the optical transceiver 30 in an assembly state may be provided as the above described inserted portion or the pressing part. In the configuration illustrated in FIG. 16, the configuration in which the protrusion portion 31a3 is formed as another member that is separately provided from the optical transceiver 30 corresponds to one example of this. Moreover, the other member may be formed by using a material having thermal conductivity that is higher than that of the body 31 of the optical transceiver 30. In this configuration, it may be said that the separated member also constitutes a part of the thermal conductive member.

In the above, examples of the embodiments have been described above, but the embodiments described above are just examples, and are not intended to limit the scope of the disclosure. The above described embodiments may be implemented in various other modes, and various omission, replacement, combinations, and modifications may be made within the scope of the disclosure. Furthermore, each of the specifications, such as the configurations and the shapes (structures, types, directions, models, sizes, lengths, widths, thicknesses, heights, numbers, arrangements, positions, materials, and the like) may be appropriately changed.

According to the present disclosure, for example, it is possible to obtain an improved novel substrate assembly capable of efficiently dissipating heat from the optical transceivers.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate assembly comprising:
a substrate configured to fix an optical transceiver, the substrate including a first surface facing a first direction and a second surface facing an opposite direction of the first direction on an opposite side of the first surface, wherein the optical transceiver includes a first electrical interface and a heat dissipation portion, and the first electrical interface and the heat dissipation portion are fixed to the substrate while facing the opposite direction and are arranged side by side with each other in a direction intersecting the first direction;
a first heat dissipation mechanism including a first part that is adjacent to the heat dissipation portion in the first direction in a state where the optical transceiver is fixed to the substrate and that is thermally connected to the heat dissipation portion; and
a thermal conductive member disposed between the heat dissipation portion and the first part.

2. The substrate assembly according to claim 1, further comprising an accommodation section configured to accommodate therein the thermal conductive member, the accommodation section being provided between the heat dissipation portion and the first part.

3. The substrate assembly according to claim 1, wherein the thermal conductive member is disposed between the heat dissipation portion and the first part while coming into contact with both of the heat dissipation portion and the first part.

4. The substrate assembly according to claim 2, wherein a height of the accommodation section is lower than a thickness of the thermal conductive member that is in an uncompressed state.

5. The substrate assembly according to claim 1, wherein the thermal conductive member includes a synthetic resin material and has flexibility.

6. The substrate assembly according to claim 1, further comprising:
the optical transceiver including a body fixed to the substrate and including the heat dissipation portion; and
a plurality of optical fibers extending from an opposite side of the heat dissipation portion of the body.

7. The substrate assembly according to claim 1, wherein the first heat dissipation mechanism includes a second part that is adjacent to the first part, and that is disposed side by side with the substrate in a direction intersecting the first direction.

8. The substrate assembly according to claim 1, wherein the first heat dissipation mechanism includes a third part that is adjacent to the first part and that passes through the substrate in the first direction.

9. The substrate assembly according to claim 8, wherein the third part is provided on the substrate.

10. The substrate assembly according to claim 8, wherein the third part is provided separately from the substrate.

11. The substrate assembly according to claim 1, wherein the first heat dissipation mechanism includes a heat transport mechanism that transports heat using a refrigerant.

12. The substrate assembly according to claim 1, wherein the first heat dissipation mechanism includes a heat sink.

13. The substrate assembly according to claim 1, wherein a semiconductor integrated circuit is mounted on the first surface.

14. The substrate assembly according to claim 13, wherein a second heat dissipation mechanism is provided on the semiconductor integrated circuit on a side opposite to a side on which the substrate is provided in a state in which the second heat dissipation mechanism is mounted on the substrate.

15. The substrate assembly according to claim 13, wherein the optical transceiver is fixed to the substrate in a state in which the heat dissipation portion is located on a side opposite to a side on which the semiconductor integrated circuit is disposed with respect to the first electrical interface.

16. The substrate assembly according to claim 1, further comprising a plurality of optical transceivers fixed to the substrate.

17. The substrate assembly according to claim 16, further comprising the plurality of optical transceivers arranged along a side of the substrate.

18. The substrate assembly according to claim 17, wherein
the plurality of optical transceivers are arranged along four sides of the substrate, and
a semiconductor integrated circuit is mounted on the first surface at a position away from each of the sides than the optical transceiver.

19. The substrate assembly according to claim 1, further comprising a fixation mechanism configured to fix the optical transceiver to the substrate.

20. The substrate assembly according to claim 19, wherein the fixation mechanism is shared with a plurality of optical transceivers as the optical transceiver.

21. The substrate assembly according to claim 19, wherein the fixation mechanism is configured to removably fix the optical transceiver to the substrate.

22. The substrate assembly according to claim 21, wherein the fixation mechanism includes a first member fixed to the substrate and a second member removably fixed to the first member and configured to press the optical transceiver toward the substrate.

23. The substrate assembly according to claim 22, further comprising:
the optical transceiver including a body fixed to the substrate, the body including the heat dissipation portion;
a plurality of optical fibers extending from a side opposite to a side on which the heat dissipation portion of the body is disposed; and
an opening through which the optical fibers pass, the opening being provided at the second member.

24. The substrate assembly according to claim 1, further comprising:
a second electrical interface fixed to the substrate and electrically connected to the first electrical interface; and
a positioning mechanism configured to position the first electrical interface and the second electrical interface.

25. The substrate assembly according to claim 1, further comprising a socket attached to the substrate, the socket including a second electrical interface electrically connected to the first electrical interface.

26. The substrate assembly according to claim 1, further comprising a flexible thermal conductive member provided between the first part and the heat dissipation portion.

27. The substrate assembly according to claim 1, wherein a plurality of substrate assemblies are mounted on an integrated substrate capable of mounting the plurality of substrate assemblies as the substrate assembly.
